(19) United States
(12) Patent Application Publication
(10) Pub. No.: US 2026/0040611 A1
(43) Pub. Date: Feb. 5, 2026

(54) SILICON-ON-INSULATOR SEMICONDUCTOR COMPONENT, PROCESS PLATFORM, AND MANUFACTURING METHOD

(71) Applicants: SOUTHEAST UNIVERSITY, Nanjing (CN); CSMC TECHNOLOGIES FAB2 CO., LTD., Wuxi (CN)

(72) Inventors: Long ZHANG, Wuxi (CN); Siyang LIU, Wuxi (CN); Nailong HE, Wuxi (CN); Chengwu PAN, Wuxi (CN); Haoyu LI, Wuxi (CN); Sen ZHANG, Wuxi (CN); Kui XIAO, Wuxi (CN); Liang SONG, Wuxi (CN); Weifeng SUN, Wuxi (CN)

(21) Appl. No.: 18/996,449

(22) PCT Filed: May 29, 2024
(86) PCT No.: PCT/CN2024/095982

§ 371 Date: Jan. 17, 2025

(30) Foreign Application Priority Data
Jun. 15, 2023 (CN) 202310713119.2

(51) Int. Cl. H10D 30/65; H01L 21/265; H01L 21/3065; H10D 12/00; H10D 12/01; H10D 30/01; H10D 62/10; H10D 86/00

(52) U.S. Cl. CPC H10D 30/657; H01L 21/265; H01L 21/3065; H10D 12/031; H10D 12/421; H10D 30/0281; H10D 62/117; H10D 86/201

(57) ABSTRACT

In one aspect, a silicon-on-insulator semiconductor device includes: a substrate; a buried dielectric layer disposed on the substrate; a first electrode; a second electrode; and a drift region disposed on the buried dielectric layer. An upper surface of the drift region forms a drop structure including a first side adjacent to the first electrode, a second side adjacent to the second electrode, and a transition region between the first side and the second side. An upper surface of the second side is higher than a bottom surface of the first side, such that a thickness of the drift region at the second side is greater than that at the first side. The first electrode and the second electrode are configured such that a voltage applied to the second electrode is greater than a voltage applied to the first electrode when a reverse bias voltage is applied to the device.

### CROSS-REFERENCE TO RELATED APPLICATIONS

This application claims priority to Chinese patent application No. 2023107131192, filed on Jun. 15, 2023, entitled “SILICON-ON-INSULATOR SEMICONDUCTOR COMPONENT, PROCESS PLATFORM, AND MANUFACTURING METHOD”, the content of which is hereby incorporated by reference in its entirety for all purposes.

### TECHNICAL FIELD

The present application relates to the field of semiconductor manufacturing, particularly to a silicon-on-insulator semiconductor device, a silicon-on-insulator semiconductor process platform, and a method for manufacturing the silicon-on-insulator semiconductor device.

### BACKGROUND

With the wide application of very large-scale integration circuit (VLSI) in various fields, the system has higher and higher requirements for the development of high-voltage and high-power semiconductor devices. Integrated high-voltage devices (such as LDMOS, LIGBT and high-voltage Diode, etc.) using silicon-on-insulator (SOI) technology have the advantages of both SOI technology and devices themselves, such as fast working speed, low parasitic effect, high breakdown voltage, simple preparation process and convenient integration, and thus have been widely studied and applied. However, conventional silicon-on-insulator integrated high-voltage devices are difficult to achieve breakdown voltages of 1200V and above. Although the thickness of the buried oxide layer is related to the breakdown voltage, a thick buried oxide layer will deteriorate the thermal conductivity of the devices. Furthermore, when thick enough, the buried oxide layer will not contribute to the breakdown voltage, and in turn an increase cost may be caused. Therefore, it is unrealistic to increase the breakdown voltage by continuously increasing the thickness of the buried oxide layer after the breakdown voltage reaches a certain value.

### SUMMARY

According to a first aspect, a silicon-on-insulator semiconductor device is provided, including: a substrate; a buried dielectric layer disposed on the substrate; a first electrode; a second electrode; and a drift region disposed on the buried dielectric layer. An upper surface of the drift region forms a drop structure including a first side adjacent to the first electrode, a second side adjacent to the second electrode, and a transition region between the first side and the second side. An upper surface of the second side is higher than a bottom surface of the first side, such that a thickness of the drift region at the second side is greater than a thickness thereof at the first side. The first electrode and the second electrode are configured such that a voltage applied to the second electrode is greater than a voltage applied to the first electrode when a reverse bias voltage is applied to the device.

In one of the embodiments, the device is a lateral double-diffused metal-oxide-semiconductor field effect transistor (LDMOS), the first electrode is a source, the second electrode is a drain, and the LDMOS further includes a gate.

In one of the embodiments, the device is a lateral insulated gate bipolar transistor (LIGBT), the first electrode is an emitter, the second electrode is a collector, and the LIGBT further includes a gate.

In one of the embodiments, the device is a diode, the first electrode is an anode, and the second electrode is a cathode.

In one of the embodiments, the drop structure is a step structure including a first step surface located on the first side, a second step surface located on the second side, and a step wall located on the transition region, and a height difference between the second step surface and the first step surface is in a range from 3 μm to 10 μm.

In one of the embodiments. an inclination angle of the step wall is in a range from 20 degrees to 90 degrees.

In one of the embodiments, the drift region has a first conductivity type, the device further includes a second conductivity type protective layer located in the drift region, and the second conductivity type protective layer encloses a corner formed by the first step surface and the step wall and a corner formed by the second step surface and the step wall; the first conductivity type is opposite to the second conductivity type.

In one of the embodiments, the device further includes a first electrode leading-out region and a second electrode leading-out region that are disposed on the buried dielectric layer.

In one of the embodiments, the device further includes a field oxide layer on the upper surface of the drift region extending from the second side adjacent to the second electrode to the first side adjacent to the first electrode.

In one of the embodiments, the device further includes an interlayer dielectric layer, the interlayer dielectric layer at least covers the field oxide layer, the first electrode leading-out region, and the second electrode leading-out region.

According to a second aspect, a silicon-on-insulator semiconductor process platform is provided, including the silicon-on-insulator semiconductor device as described in any one of the above embodiments, and further including at least one of a complementary metal-oxide-semiconductor field effect transistor (CMOS) and a well resistor.

According to a third aspect, a method for manufacturing a silicon-on-insulator semiconductor device is provided, including: obtaining a wafer including a substrate, a buried dielectric layer on the substrate, and a drift region on the buried dielectric layer; forming a drop structure on an upper surface of the drift region by photolithography and etching, wherein the drop structure includes a first side, a second side, and a transition region between the first side and the second side, and an upper surface of the second side is higher than a bottom surface of the first side, such that a thickness of the drift region at the second side is greater than a thickness thereof at the first side; and forming a first electrode and a second electrode. The first side is a side adjacent to the first electrode, and the second side is a side adjacent to the second electrode. The first electrode and the second electrode are configured such that a voltage applied to the second electrode is greater than a voltage applied to the first electrode when a reverse bias voltage is applied to the device.

In one of the embodiments, the drop structure is a step structure including a first step surface on the first side, a second step surface on the second side, and a step wall on the transition region. Prior to forming the first electrode and the second electrode, the method further includes: forming a protective layer in the drift region at the step structure by ion implantation, and the protective layer encloses a corner formed by the first step surface and the step wall and a corner formed by the second step surface and the step wall.

In one of the embodiments, the etching is a reactive ion etching process.

According to a fourth aspect, a method for manufacturing a silicon-on-insulator semiconductor device is provided, including: obtaining a wafer comprising a substrate, a buried dielectric layer on the substrate, and a first epitaxial layer on the buried dielectric layer; forming a second epitaxial layer at a partial region of the first epitaxial layer, wherein a drop structure is formed at a boundary between the first epitaxial layer and the second epitaxial layer, the drop structure includes a first side on a side of the second epitaxial layer, a second side on a side of the first epitaxial layer, and a transition region between the first side and the second side; and forming a first electrode and a second electrode. The first side is a side adjacent to the first electrode, and the second side is a side adjacent to the second electrode. The first electrode and the second electrode are configured such that a voltage applied to the second electrode is greater than a voltage applied to the first electrode when a reverse bias voltage is applied to the device.

Details of one or more embodiments of the present disclosure are set forth in the accompanying drawings and description below. Other features, objects, and advantages of the present disclosure will become apparent from the description, accompanying drawings, and claims.

### BRIEF DESCRIPTION OF THE DRAWINGS

In order to better describe and illustrate embodiments and/or examples of the present disclosure disclosed herein, reference may be made to one or more accompanying drawings. Additional details or examples used to describe the accompanying drawings should not be considered as limitations on the scope of any of the disclosed contents, the presently described embodiments and/or examples, and the presently understood best mode of the present disclosure.

FIG. 1 is a schematic cross-sectional structural view of a silicon-on-insulator semiconductor device in an embodiment where the device is an LDMOS.

FIG. 2a is a schematic cross-sectional view of an SOI LDMOS formed with a single-piece protective layer according to an embodiment. FIG. 2b is a schematic cross-sectional view of an SOI LDMOS formed with protective layers respectively enclose two corners according to an embodiment, and FIG. 2c is a schematic cross-sectional view of an SOI LDMOS formed by a secondary epitaxy method according to an embodiment.

FIG. 3 is a schematic cross-sectional structural view of a silicon-on-insulator semiconductor device in an embodiment where the device is an LIGBT.

FIG. 4 is a schematic cross-sectional view of an LIGBT formed by a secondary epitaxy method according to an embodiment.

FIG. 5 is a schematic cross-sectional structural view of a silicon-on-insulator semiconductor device in an embodiment where the device is a diode.

FIG. 6 is a schematic cross-sectional view of a diode formed by a secondary epitaxy method according to an embodiment.

FIG. 7 is a schematic cross-sectional structural view of a silicon-on-insulator semiconductor process platform according to an embodiment of the present disclosure.

FIG. 8 shows a flowchart of a method for manufacturing a silicon-on-insulator semiconductor device according to an embodiment of the present disclosure.

FIG. 9 shows a flowchart of a method for manufacturing a silicon-on-insulator semiconductor device according to another embodiment of the present disclosure.

FIG. 10 shows a flowchart of the steps between steps S420 and S430 according to an embodiment where the manufactured device is an SOILDMOS.

FIGS. 11a to 11e are schematic cross-sectional views of parts during the method for manufacturing an SOI LDMOS as shown in FIG. 10.

FIG. 12 shows a flowchart of the steps between steps S420 and S430 according to an embodiment where the manufactured device is an SOI LIGBT.

FIGS. 13a to 13e are schematic cross-sectional views of parts during the method for manufacturing an SOI LIGBT as shown in FIG. 12.

FIG. 14 shows a flowchart of the steps between steps S420 and S430 according to an embodiment where the manufactured device is a diode.

FIGS. 15a to 15d are schematic cross-sectional views of parts during the method for manufacturing an SOI diode as shown in FIG. 14.

FIG. 16 is a schematic cross-sectional structural view of a silicon-on-insulator semiconductor process platform according to an embodiment where a step structure of a drift region is formed by reactive ion etching.

FIG. 17 is a schematic cross-sectional structural view of a silicon-on-insulator semiconductor process platform according to an embodiment where a step structure of a drift region is formed by a secondary epitaxy method.

### DETAILED DESCRIPTION

For easy understanding of the present disclosure, a more comprehensive description of the present disclosure is given below with reference to the accompanying drawings. Preferred embodiments of the present disclosure are illustrated in the accompanying drawings. However, the present disclosure may be implemented in many different forms and is not limited to the embodiments described herein. Rather, these embodiments are provided to make the contents disclosed in the present disclosure more thoroughly and comprehensive.

Unless otherwise defined, all technical and scientific terms used herein have the same meaning as commonly understood by those of ordinary skill in the art to which the present disclosure belongs. The terms used in the specification of the present disclosure are intended only to describe specific embodiments and are not intended to limit the present disclosure. The term “and/or” used herein includes any and all combinations of one or more of the associated listed items.

It should be understood that when an element or layer is referred to as being “on”. “adjacent to”, “connected to”, or “coupled to” another element or layer, the element or layer may be directly on, adjacent to, connected to, or coupled to another element or layer, or an intervening element or layer may be provided therebetween. On the contrary, when an element is referred to as being “directly on”, “directly adjacent to”, “directly connected to”, or “directly coupled to” another element or layer, no intervening element or layer may be provided therebetween. In the present specification, term “connection” should be understood as “electrical connection”, “communication connection”, or the like, if the connected circuits, modules, units, or the like have electrical signal or data transmission between each other. It should be understood that, although terms such as “first”, “second”, and “third” may be used to describe various elements, components, regions, layers, and/or portions, the elements, components, regions. layers, and/or portions may not be limited to such terms. Such terms are used only to distinguish one element, component, region, layer, or portion from another element, component, region, layer, or portion. Thus, without departing from the teaching of the present disclosure, a first element, component, region, layer, or portion may be referred to as a second element, component, region, layer, or portion.

Spatial relationship terms such as “under”, “underneath”, “below”, “beneath”, “over”, and “above” may be used for illustrative purposes to describe a relationship between one element or feature and another element or feature illustrated in the figures. It should be understood that, in addition to the orientations illustrated in the figures, the spatial relationship terms are intended to further include different orientations of the device in use and operation. For example, if the device in the figures is flipped, an element or a feature described as “below”, “underneath” or “under” another element or feature may be oriented as “on” the another element or feature. Thus, the exemplary terms “below” and “under” may include two orientations of above and below. In addition, the device may be additionally orientated (e.g., rotated by 90-degree or orientated in other ways), and thus spatial descriptors used herein may be interpreted accordingly.

The terms used herein are for the purpose of describing specific embodiments only and are not intended to limit the present disclosure. In use, the singular forms of “a/an”, “one”, and “the” may also include plural forms, unless otherwise clearly specified in the context. It should be understood that “at least one” refers to one or more, “plurality of” refers to two or more, and “At least a portion of an element” refers to a portion or all of an element. It should be further understood that the terms “composed of” and/or “including/comprising” when used in this specification specify the presence of the features, integers, steps, operations, elements, and/or components, but may not exclude the presence or addition of one or more of other features, integers, steps, operations, elements, components, and/or groups. When used herein, the term “and/or” may include any and all combinations of associated listed items.

Embodiments of the present disclosure are described herein with reference to cross-sectional views that are schematic views of ideal embodiments (and intermediate structures) of the present disclosure, so that variants in the shapes shown due to, for example, manufacturing techniques and/or tolerances can be expected. Therefore, embodiments of present disclosure should not be limited to the specific shapes of the regions shown herein, and includes shape deviations due to, for example, manufacturing techniques. For example, an implantation region shown as a rectangle generally has rounded or curved features and/or an injected concentration gradient at its edges, rather than a binary change from the implantation region to a non-implantation region. Similarly, a buried region formed by implantation may result in some implantations in the region between the buried region and the surface through which the implantation takes place. Therefore, the regions shown in the figures are schematic in nature, their shapes do not represent the actual shape of the region of the device, and do not limit the scope of the present disclosure.

The vocabulary in the semiconductor field used herein is a technical vocabulary commonly used by those skilled in the art. For example, for P-type and N-type impurities, in order to distinguish doping concentration, it is simple to use P+ type to represent P type of heavy doping concentration, use P type to represent P type of medium doping concentration, use P− type to represent P type of light doping concentration, use N+ type to represent N type of the heavy doping concentration, use N type to represent N type of the medium doping concentration, and use N− type to represent N type of the light doping concentration.

For conventional SOI semiconductor process platforms, integrated high-voltage devices usually can only reach a breakdown voltage of 600V, but are difficult to reach a breakdown voltage greater than or equal to 1200V. Moreover, the withstand voltages of the integrated high-voltage devices cannot be increased to 1200V or greater by thickening the top silicon, because only increasing the thickness of the top silicon cannot solve the problem of longitudinal early breakdown. An exemplary SOI semiconductor process platform uses the structure of a thick buried oxide layer and a thin top silicon, which can enable the integrated high-voltage device to reach a breakdown voltage of 1200V. This is because the breakdown voltage of the device will increase with the increase of the thickness of the buried oxide layer within a certain range, and the thin top silicon limits the energy obtained by the carriers through the longitudinal electric field, making the device less likely to be broken down. However, this solution has obvious deficiencies: the buried oxide layer of SOI structure blocks the heat conduction to the substrate, which leads to poor heat dissipation of the device, causing the local lattice temperature of the device to rise, and thus causing the electrical parameters of the device to degrade. These degradation phenomena deteriorate the reliability of the device, especially for devices with thick buried oxide layers.

The present disclosure provides a silicon-on-insulator semiconductor device including: a substrate; a buried dielectric layer disposed on the substrate; a first electrode; a second electrode; and a drift region disposed on the buried dielectric layer. An upper surface of the drift region forms a drop structure including a first side adjacent to the first electrode, a second side adjacent to the second electrode, and a transition region between the first side and the second side. An upper surface of the second side is higher than a bottom surface of the first side, such that a thickness of the drift region at the second side is greater than a thickness thereof at the first side. The first electrode and the second electrode are configured such that a voltage applied to the second electrode is greater than a voltage applied to the first electrode when a reverse bias voltage is applied to the device.

The silicon-on-insulator semiconductor device adopts a structure in which the thickness of the drift region at the low-voltage end of the device is less than that of the drift region at the high-voltage end when the reverse bias voltage is applied, so that the breakdown point of the device can be controlled to be below the high-voltage end, which allows the drift region to be completely exhausted. As a result, the breakdown voltage of the device can be increased without increasing the thickness of the buried oxide layer.

In an embodiment of the present disclosure, the silicon-on-insulator semiconductor device further includes a first electrode leading-out region and a second electrode leading-out region that are disposed on the buried dielectric layer, and have P-type doping or N-type doping. The first electrode is located on the first electrode leading-out region, and electrically connected to the first electrode leading-out region. The second electrode is located on the second electrode leading-out region, and electrically connected to the second electrode leading-out region.

In an embodiment of the present disclosure, the drift region has a first conductivity type. The device further includes a second conductivity type protective layer located in the drift region, and the second conductivity type protective layer encloses a corner formed by the first step surface and the step wall and a corner formed by the second step surface and the step wall. The first conductivity type is opposite to the second conductivity type.

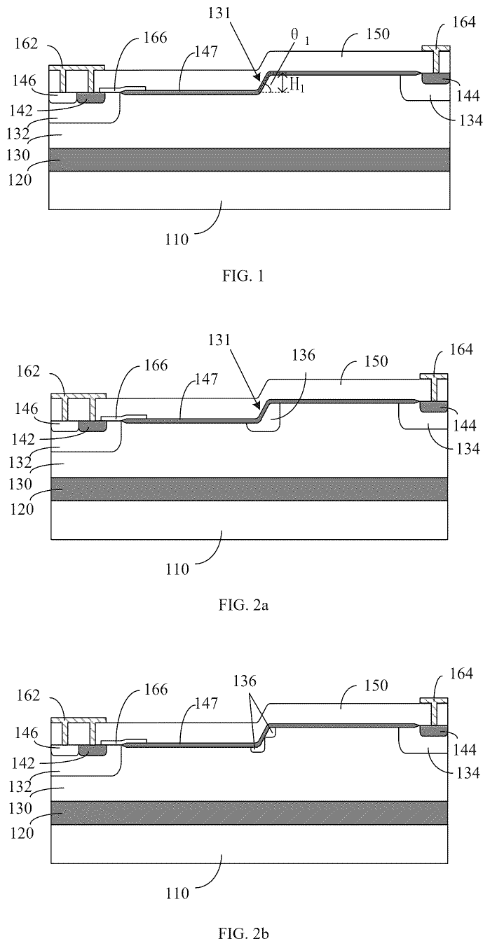

FIG. 1 is a schematic cross-sectional structural view of a silicon-on-insulator semiconductor device in an embodiment where the device is a lateral double-diffused metal-oxide-semiconductor field effect transistor (LDMOS). The LDMOS includes a substrate 110, a buried dielectric layer 120, a drift region 130, a first electrode 162, a second electrode 164, and a gate 166. The first electrode 162 is a source, and the second electrode 164 is a drain. An upper surface of the drift region 130 is higher on a side adjacent to the drain (hereinafter referred to as a drift region high side) than on a side adjacent to the source (hereinafter referred to as a drift region low side), thereby forming a drop structure 131.

The LDMOS further includes a first electrode leading-out region (i.e., a source region) 142 located on the drift region low side and a second electrode leading-out region (i.e., a drain region) 144 located on the drift region high side. The first electrode (i.e., the source) 162 is located on the first electrode leading-out region 142, and is electrically connected to the first electrode leading-out region 142. The second electrode (i.e., the drain) 164 is located on the second electrode leading-out region 144, and is electrically connected to the second electrode leading-out region 144. In the embodiment shown in FIG. 1, the gate 166 extends from the drift region low side to an edge of the first electrode leading-out region 142, and can overlap with the first electrode leading-out region 142 by a certain area.

In the embodiment shown in FIG. 1. the LDMOS further includes a field oxide layer 147 extending from the drift region high side to the drift region low side. A portion of the gate 166 extends onto the field oxide layer 147.

In the embodiment shown in FIG. 1, the LDMOS is an N-type LDMOS, the drift region 130 is an N-type drift region. The LDMOS further includes a P-type body region 132 located on the drift region low side and an N-well 134 located on the drift region high side. The first electrode leading-out region 142 is an N+ region and is in the P-type body region 132. The second electrode leading-out region 144 is an N+ region and is in the N-well 134.

In the embodiment shown in FIG. 1, the LDMOS further includes a body leading-out region 146 in the P-type body region 132. The body leading-out region 146 is a P+ region. The first electrode 162 is electrically connected to the body leading-out region 146.

In an embodiment of the present disclosure, the LDMOS further includes an interlayer dielectric (ILD) layer 150. The interlayer dielectric layer 150 covers structures such as the gate 166, the field oxide layer 147, the first electrode leading-out region 142, the second electrode leading-out region 144, and the body leading-out region 146.

In an embodiment of the present disclosure, the buried dielectric layer 120 is a buried oxide layer, and the material thereof can be silicon dioxide.

In an embodiment of the present disclosure, the drop structure is a step structure including a first step surface on the first side, a second step surface on the second side, and a step wall on the transition region. The height difference (corresponding to H₁ in FIG. 1) between the second step surface and the first step surface is in a range from 3 μm to 10 μm. An appropriate height difference can ensure that the drift region can be completely exhausted. An inclination angle (corresponding to θ₁ in FIG. 1) of the step wall is in a range from 20 degrees to 90 degrees. An appropriate inclination angle of θ₁ can ensure that the device will not be broken down in advance at this angle.

When a reverse bias voltage is applied to the LDMOS, a positive voltage is applied to the drain, and the gate 166, the source, and the substrate are grounded. A PN junction formed by the P-type body region 132 and the N-type drift region 130 is reversely biased. As the applied bias voltage increases, the space charge region in the low-doped drift region 130 expands to the drain end. The depletion region in the drift region 130 can extend to the upper surface of the buried oxide layer at most, and the electric field in the depletion region can be almost unaffected by the substrate 110. The presence of the buried oxide layer improves the longitudinal withstand voltage of the device and avoids early breakdown in the longitudinal direction when the depletion region expands to the drain end. Meanwhile, the thickness of the drift region at the source end is less than the thickness of the drift region at the drain end, so that the depletion region tends to expand toward the drain end when the device works in the reverse withstand voltage state, and can be exhausted from the source end to the drain end more easily, allowing the drift region 130 to be completely exhausted before longitudinal breakdown, and controlling the breakdown point at the boundary between the drain drift region and the buried oxide layer. As such, the breakdown voltage of the device can still be increased without increasing the thickness of the buried oxide layer, and the breakdown voltage of the device can be greater than or equal to 1200V.

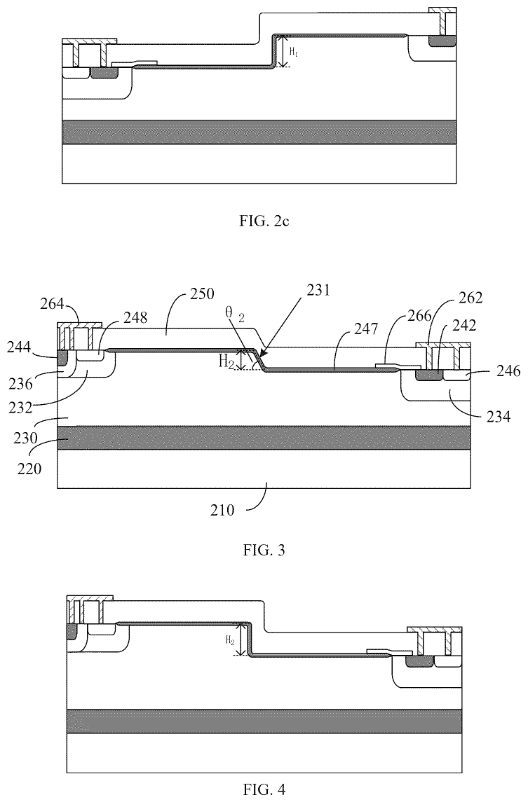

Referring to FIG. 2a, in an embodiment of the present disclosure, the LDMOS further includes a protective layer 136. The protective layer 136 is located in the drift region 130, and has a conductivity type opposite to that of the drift region 130. The protective layer 136 encloses a corner formed by the first step surface and the step wall and a corner formed by the second step surface and the step wall. The protective layer 136 may be a single-piece structure as shown in FIG. 2a, or may be a structure respectively enclosing two comers as shown in FIG. 2b. By forming the protective layer having the conductivity type opposite to that of the drift region 130 at the corner of the step, early breakdown of the device due to the concentration of electric field lines caused by the corner of the step can be avoided.

In some embodiments of the present disclosure, the step structure of the aforementioned drift region of the silicon-on-insulator semiconductor device may be formed by a reactive ion etching (RIE) method or a secondary epitaxy method. The secondary epitaxy method can obtain a more “vertical” step of the drift region, as shown in FIG. 2c. FIG. 2c shows an LDMOS formed by the secondary epitaxy method, which mainly differs from the structure shown in FIG. 1 in that the step structure is steeper. The specific structure will not be described herein. The structure shown in FIG. 1 may be formed by reactive ion etching. If a method of primary epitavy and reactive ion etching or a method of secondary epitaxy is adopted to form the step structure of the drift region provided in the present disclosure, a 1200V silicon-on-insulator semiconductor process platform can be achieved. If the conventional primary epitaxy method is adopted, the 600V silicon-on-insulator semiconductor process platform can be achieved. Therefore, the 1200V process platform provided in the present disclosure can be compatible with the 600V process platform and has good compatibility.

FIG. 3 is a schematic cross-sectional structural view of a silicon-on-insulator semiconductor device in an embodiment where the device is a lateral insulated gate bipolar transistor (LIGBT). The LIGBT includes a substrate 210, a buried dielectric layer 220, a drift region 230, a first electrode 262, a second electrode 264, and a gate 266. The first electrode 262 is an emitter, and the second electrode 264 is a collector. An upper surface of the drift region 230 is higher on a side adjacent to the collector (hereinafter referred to as a drift region high side) than on a side adjacent to the emitter (hereinafter referred to as a drift region low side), thereby forming a drop structure 231.

The LIGBT in the embodiment shown in FIG. 3 is an N-type LIGBT, the drift region 230 is an N-type drift region. The LIGBT further includes a first P-type body region 234, a second body region 236, and an N-well 232. The N-well 232 and the second body region 236 are located on the drift region high side. The first body region 234 is located on the drift region low side. A first N+ region 242 and a first P+ region 246 are disposed in the first body region 234, and are electrically connected to the emitter 262. A second P+ region 248 is disposed in the N-well 232, and a second N+ region 244 is disposed in the second body region 236. The collector 264 is electrically connected to a second N+ region 244, a second P+ region 248, and the second body region 236. In the embodiment shown in FIG. 3, the gate 266 extends from the drift region low side to an edge of the first N+ region 242, and can overlap with the first N+ region 242 by a certain area. When a reverse bias voltage is applied to the LIGBT, a high voltage is applied to the collector, and a low voltage is applied to the emitter, or the emitter is grounded.

In the embodiment shown in FIG. 3, the LIGBT further includes a field oxide layer 247 extending from the drift region high side to the drift region low side. A portion of the gate 266 extends onto the field oxide layer 247.

In an embodiment of the present disclosure, the LIGBT further includes an interlayer dielectric (ILD) layer 250. The interlayer dielectric layer 250 covers structures such as the gate 266, the field oxide layer 247, the first N+ region 242, the first P+ region 246, the second N+ region 244, the second P+ region 248, and the second body region 236.

The step structure of the drift region of the LIGBT may also be formed by a reactive ion etching method or a secondary epitaxy method. The secondary epitaxy method can obtain a more “vertical” step of the drift region, as shown in FIG. 4. FIG. 4 mainly differs from FIG. 3 in that the step structure is steeper. The specific structure will not be described herein. The structure shown in FIG. 3 may be formed by reactive ion etching, the height difference between the second step surface and the first step surface is in a range from 3 μm to 10 μm, and the inclination angle θ₂ of the step wall is in a range from 20 degrees to 90 degrees.

In an embodiment of the present disclosure, the LIGBT further includes a protective layer. The protective layer is located in the drift region, has a conductivity type opposite to that of the drift region, and encloses a corner formed by the first step surface and the step wall and a corner formed by the second step surface and the step wall. The protective layer may be a single-piece structure, or may be a structure respectively enclosing two corners.

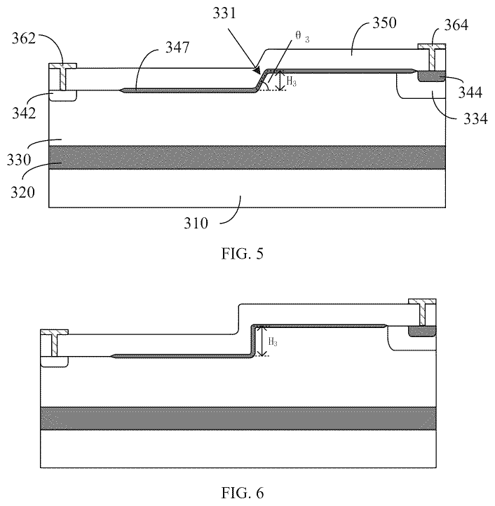

FIG. 5 is a schematic cross-sectional structural view of a silicon-on-insulator semiconductor device in an embodiment where the device is a diode. The diode includes a substrate 310, a buried dielectric layer 320, a drift region 330, a first electrode 362, a second electrode 364. The first electrode 362 is an anode, and the second electrode 364 is a cathode. An upper surface of the drift region 330 is higher on a side adjacent to the cathode (hereinafter referred to as a drift region high side) than on a side adjacent to the anode (hereinafter referred to as a drift region low side), thereby forming a drop structure 331.

The diode further includes a first electrode leading-out region (i.e., an anode region) 342 located on the drift region low side and a second electrode leading-out region (i.e., a cathode region) 344 located on the drift region high side. The first electrode (i.e., the anode) 362 is located on the first electrode leading-out region 342, and electrically connected to the first electrode leading-out region 342. The second electrode (i.e., the cathode electrode) 364 is located on the second electrode leading-out region 344, and electrically connected to the second electrode leading-out region 344. In the embodiment shown in FIG. 1, the gate 166 extends from the drift region low side to an edge of the first electrode leading-out region 142, and can overlap with the first electrode leading-out region 142 by a certain area. When a reverse bias voltage is applied to the diode, a high voltage is applied to the cathode, and a low voltage is applied to the anode, or the anode is grounded.

In the embodiment shown in FIG. 5, the drift region 330 is an N-type drift region. The diode further includes an N-well 334 located on the drift region high side. The second electrode leading-out region 344 is an N+ region and is in the N-well 334. The first electrode leading-out region 342 is a P+ region and is located in the drift region low side.

In the embodiment shown in FIG. 5, the diode further includes a field oxide layer 347 extending from the drift region high side to the drift region low side.

In an embodiment of the present disclosure, the diode further includes an interlayer dielectric (ILD) layer 350. The interlayer dielectric layer 350 covers structures such as the field oxide layer 347, the first electrode leading-out region 342, and the second electrode leading-out region 344.

The step structure of the drift region of the diode may also be formed by a reactive ion etching method or a secondary epitaxy method. The secondary epitaxy method can obtain a more “vertical” step of the drift region. as shown in FIG. 6. FIG. 6 mainly differs from FIG. 5 in that the step structure is steeper. The specific structure will not be described herein. The structure shown in FIG. 5 may be formed by reactive ion etching, the height difference between the second step surface and the first step surface is in a range from 3 μm to 10 μm, and the inclination angle θ₃ of the step wall is in a range from 20 degrees to 90 degrees.

In an embodiment of the present disclosure, the diode further includes a protective layer. The protective layer is located in the drift region, has a conductivity type opposite to that of the drift region, and encloses a corner formed by the first step surface and the step wall and a corner formed by the second step surface and the step wall. The protective layer may be a single-piece structure, or may be a structure respectively enclosing two comers.

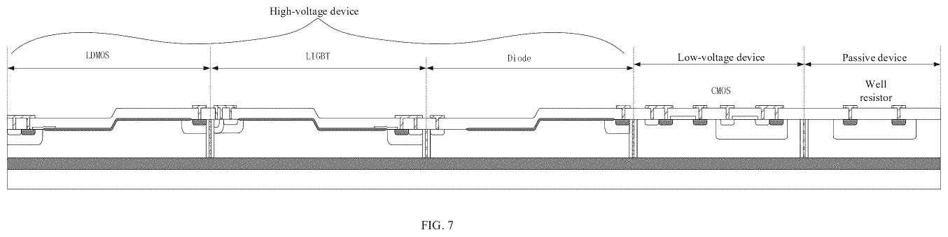

The present disclosure also provides a silicon-on-insulator semiconductor process platform, which includes a silicon-on-insulator semiconductor device as described in any one of the above embodiments, and further includes a low-voltage device and/or a passive device. In an embodiment of the present disclosure, the low-voltage device can be a complementary metal-oxide-semiconductor field effect transistor (CMOS), and the passive device may be a well resistor. FIG. 7 is a schematic cross-sectional structural diagram of a silicon-on-insulator semiconductor process platform according to an embodiment of the present disclosure. In the embodiment shown in FIG. 7, the silicon-on-insulator semiconductor process platform includes an LDMOS, an LIGBT, a diode, a CMOS, and a well resistor. The structures of LDMOS, LIGBT and diode have been introduced in the above and will not be described herein. Different devices are isolated from each other by isolation structures. The height of the upper surface of the drift region of the CMOS and the well resistor is the same as the height of the drift region high side.

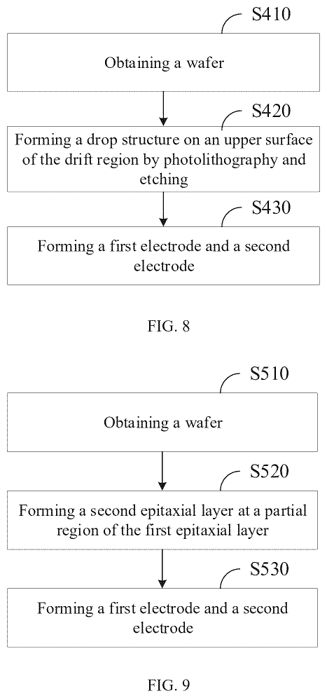

The present disclosure correspondingly provides a method for manufacturing a silicon-on-insulator semiconductor device, which can be used for manufacturing the silicon-on-insulator semiconductor device as described in any one of the above embodiments. FIG. 8 is a flowchart of a method for manufacturing a silicon-on-insulator semiconductor device according to an embodiment of the present disclosure, in which the step structure of the drift region is formed by etching, and the manufacturing method includes the following steps of:
S410, a wafer is obtained.

The wafer includes a substrate, a buried dielectric layer on the substrate, and a drift region on the buried dielectric layer, and the drift region can be formed on a buried oxide layer by an epitaxy method.
S420, a drop structure is formed on an upper surface of the drift region by photolithography and etching.

A certain thickness of the drift region (epitaxial layer) in the exposed region of the photoresist is etched. so that the thickness of the epitaxial layer corresponding to the etched region is smaller than the thickness of other portions of the epitaxial layer. That is, the drop structure includes a first side, a second side, and a transition region between the first side and the second side. The upper surface of the second side is higher than the lower surface of the first side, so that the thickness of the drift region on the second side is greater than that on the first side.

In an embodiment of the present disclosure, the etching specifically is a reactive ion etching process, which has good anisotropy and can obtain a relatively steep transition region. Moreover, the reactive ion etching process has a fast etching-speed, and can accurately control the etching depth.
S430, a first electrode and a second electrode are formed.

The first side is a side adjacent to the first electrode, and the second side is a side adjacent to the second electrode.

According to the method for manufacturing a silicon-on-insulator semiconductor device, the manufactured device has a structure in which the thickness of the drift region at the low-voltage end of the device is less than the thickness of the drift region at the high-voltage end (when reverse bias is applied), so that the breakdown point of the device can be controlled to be below the high-voltage end, which allows the drift region to be completely exhausted. As a result, the breakdown voltage of the device can be increased without increasing the thickness of the buried oxide layer.

In an embodiment of the present disclosure, after step S420 and prior to step S430, the method further includes a step of forming a protective layer in the drift region at the step structure by ion implantation. The protective layer encloses a corner formed by the first step surface and the step wall and a corner formed by the second step surface and the step wall. The conductivity type of the protective layer is opposite to the conductivity type of the drift region. The protective layer can be a single-piece structure, or can be a structure respectively enclosing two corners. In an embodiment in which the protective layer is a single-piece structure, the length of the implantation window of the protective layer (the longitudinal direction is the longitudinal direction of the conductive channel) is 110% to 120% of the length of the transition region (the longitudinal direction is the longitudinal direction of the conductive channel). FIG. 16 is a schematic cross-sectional structural view of a silicon-on-insulator semiconductor process platform in an embodiment where the step structure of the drift region is formed by reactive ion etching, in which the protective layer is a single-piece structure. In an embodiment in which the protective layer is a structure respectively enclosing two comers, the length of each implantation window of the protective layer is 5% to 10% of the length of the transition region.

FIG. 9 is a flowchart of a method for manufacturing a silicon-on-insulator semiconductor device according to another embodiment of the present disclosure, in which the step structure of the drift region is formed by secondary epitaxy, and the manufacturing method includes the following steps of:
S510: a wafer is obtained.

The wafer includes a substrate, a buried dielectric layer on the substrate, and a first epitaxial layer on the buried dielectric layer.
S520, a second epitaxial layer at a partial region of the first epitaxial layer is formed.

A part of the surface of the first epitaxial layer can be exposed by photolithography, then followed by epitaxy, and the second epitaxial layer can be formed in the exposed region. As such, the drop structure is formed at a boundary between the first epitaxial layer and the second epitaxial layer. The drop structure includes a first side on a side of the second epitaxial layer, a second side on a side of the first epitaxial layer, and a transition region between the first side and the second side.
S530, a first electrode and a second electrode are formed.

In an embodiment, the drop structure is a step structure including a first step surface located on the first side, a second step surface located on the second side, and a step wall located on the transition region. The height difference between the second step surface and the first step surface is in a range from 3 μm to 10 μm. The inclination angle of the step wall is in a range from 20 degrees to 90 degrees.

In an embodiment of the present disclosure, after step S520 and prior to step S530, the method further includes a step of forming a protective layer in the drift region at the step structure by ion implantation. The protective layer encloses a corner formed by the first step surface and the step wall and a corner formed by the second step surface and the step wall. The conductivity type of the protective layer is opposite to the conductivity type of the drift region. The protective layer can be a single-piece structure, or can be a structure respectively enclosing two comers. In an embodiment in which the protective layer is a single-piece structure, the length of the implantation window of the protective layer (the longitudinal direction is the longitudinal direction of the conductive channel) is 110% to 120% of the length of the transition region (the longitudinal direction is the longitudinal direction of the conductive channel). In an embodiment in which the protective layer is a structure respectively enclosing two comers, the length of each implantation window of the protective layer is 5% to 10% of the length of the transition region. FIG. 17 is a schematic cross-sectional structural view of a silicon-on-insulator semiconductor process platform in an embodiment where the step structure of the drift region is formed by secondary epitaxy, in which the protective layer is a structure respectively enclosing two comers.

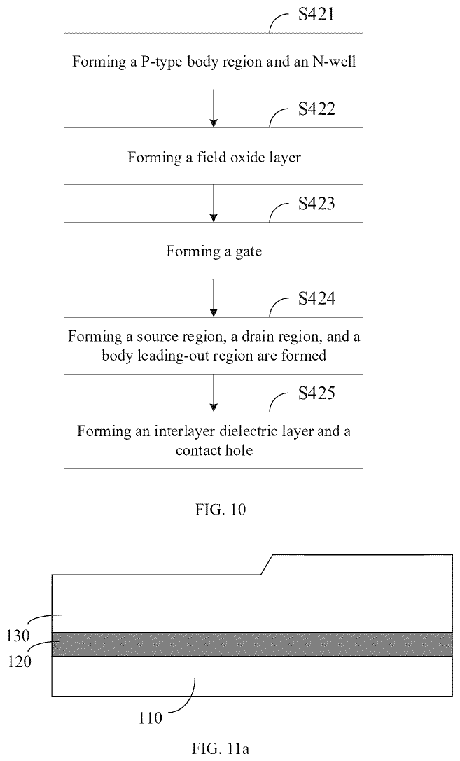

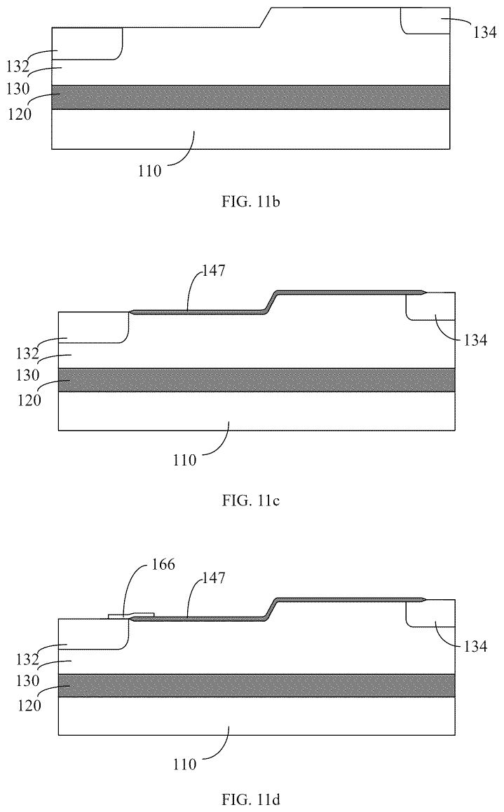

Taking the manufacturing of the SOI LDMOS as an example, the structure after step S420 is shown in FIG. 11a. Referring to FIG. 10, the method for manufacturing the SOI LDMOS further includes the following steps after step S420:
S421, a P-type body region and an N-well are formed.

Referring to FIG. 11b, the P-type body region 132 and the N-well 134 can be formed by photolithography and ion implantation. The P-type body region 132 is formed on a first side of the drop structure, and an N-well 134 is formed on a second side of the drop structure.
S422, a field oxide layer is formed.

Referring to FIG. 11c, the field oxide layer 147 is formed on the surface of the drift region 130 and between the P-type body region 132 and the N-well 134. The field oxide layer 147 can be formed by deposition or thermal oxidation.
S423, a gate is formed.

In the embodiment shown in FIG. 11d, the gate 166 extends from the P-type body region 132 onto the field oxide layer 147. The gate 166 can be made of polysilicon. The gate 166 may be formed by deposition, photolithography, or etching.
S424, a source region, a drain region, and a body leading-out region are formed.

Referring to FIG. 11e, an N+ source region (i.e., a first electrode leading-out region 142) is formed in the P-type body region 132, an N+ drain region (i.e., a second electrode leading-out region 144) is formed in an N-well 134, and a P+ body leading-out region 146 is formed in the P-type body region 132.
S425, an interlayer dielectric layer and a contact hole are formed.

The interlayer dielectric layer 150 is deposited, and then etched to form the contact hole. Thereafter, step S430 is performed to form the first electrode 162 and the second electrode 164, that is, the structure shown in FIG. 1 is obtained. The first electrode 162 is electrically connected to the N+ source region, and the second electrode 164 is electrically connected to the N+ drain region. The above steps S421 to S425 are suitable for the embodiment in which the step structure of the drift region is formed by reactive ion etching, and also suitable for the embodiment in which the step structure of the drift region is formed by secondary epitaxy, except that the step structure formed by secondary epitaxy is steeper.

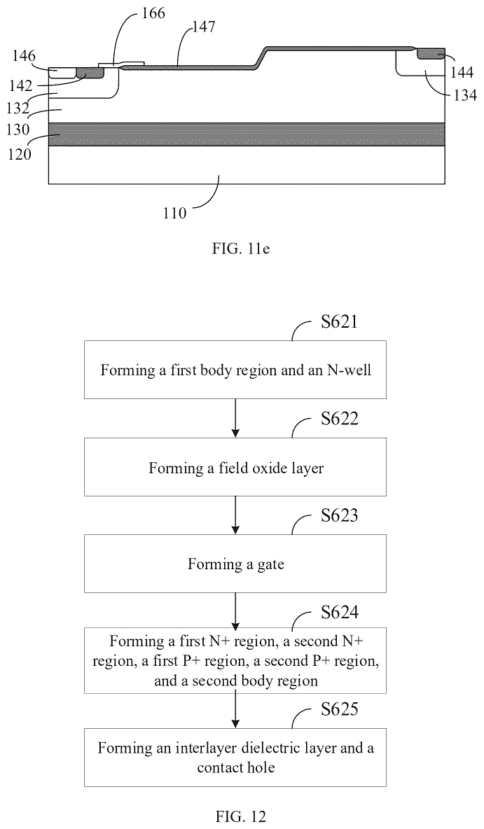

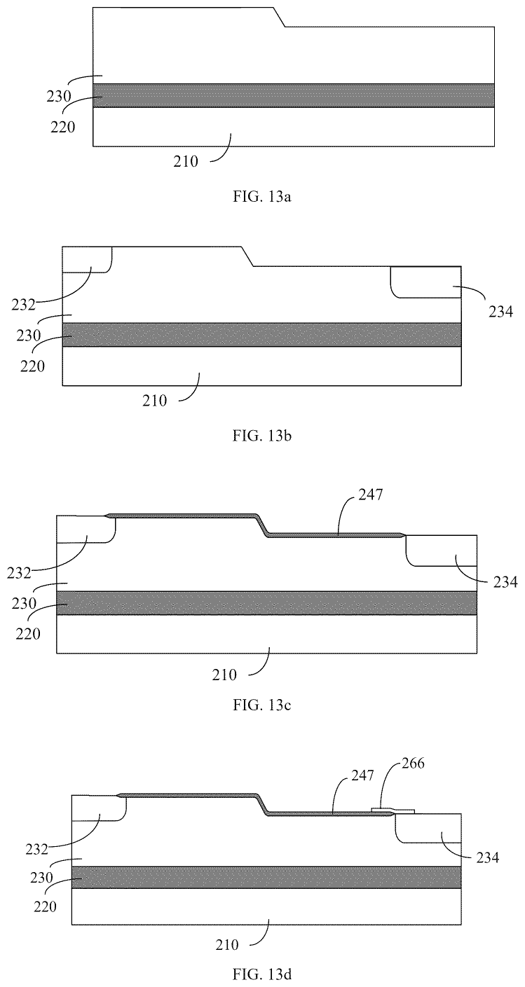

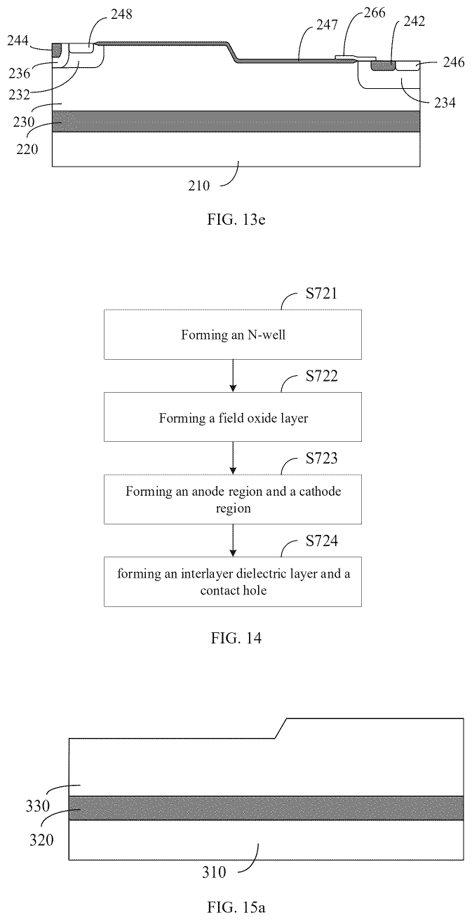

Taking the manufacturing of the SOI LIGBT as an example, the structure after step S420 is shown in FIG. 13a. Referring to FIG. 12, the method for manufacturing the SOI LIGBT further includes the following steps after step S420:
S621, a first body region and an N-well are formed.

Referring to FIG. 13b, the first body region 234 and the N-well 232 can be formed by photolithography and ion implantation. The first body region 234 is formed on a first side of the drop structure, and an N-well 232 is formed on a second side of the drop structure.
S622, a field oxide layer is formed.

Referring to FIG. 13c, the field oxide layer 247 is formed on the surface of the drift region 130 and between the first body region 234 and the N-well 232. The field oxide layer 247 can be formed by deposition or thermal oxidation.
S623, a gate is formed.

In the embodiment shown in FIG. 13d, the gate 266 extends from the first body region 234 onto the field oxide layer 247. The gate 266 can be made of polysilicon. The gate 266 can be formed by deposition, photolithography, or etching.
S624: a first N+ region, a second N+ region, a first P+ region, a second P+ region, and a second body region are formed.

Referring to FIG. 13e, the first N+ region 242 and the first P+ region 246 are formed in the first body region 234, the second P+ region 248 is formed in the N-well 232, and the second N+ region 244 is formed in the second body region 236.
S625, an interlayer dielectric layer and a contact hole are formed.

The interlayer dielectric layer 250 is deposited, and then etched to form the contact hole. Thereafter, step S430 is performed to form the first electrode 262 and the second electrode 264, that is, the structure shown in FIG. 3 is obtained. The first electrode 262 is electrically connected to the first N+ region 242 and the first P+ region 246, and the second electrode 264 is electrically connected to the second P+ region 248, the second N+ region 244 and the second body region 236. The above steps S621 to S625 are suitable for the embodiment in which the step structure of the drift region is formed by reactive ion etching, and also suitable for the embodiment in which the step structure of the drift region is formed by secondary epitaxy, except that the step structure formed by secondary epitaxy is steeper.

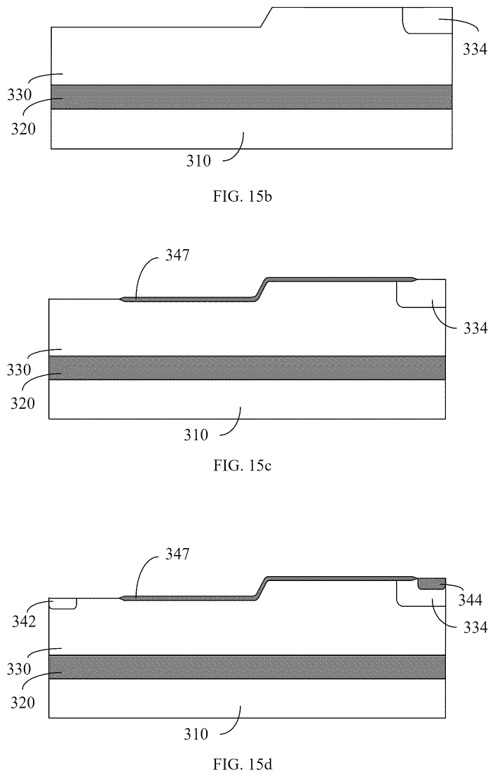

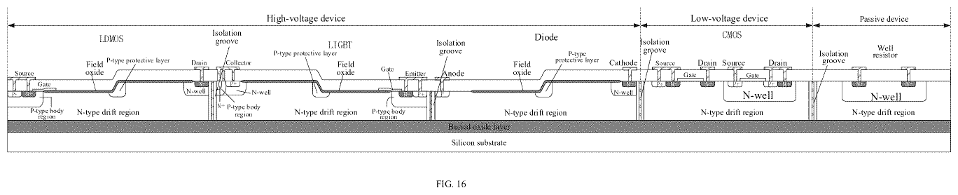

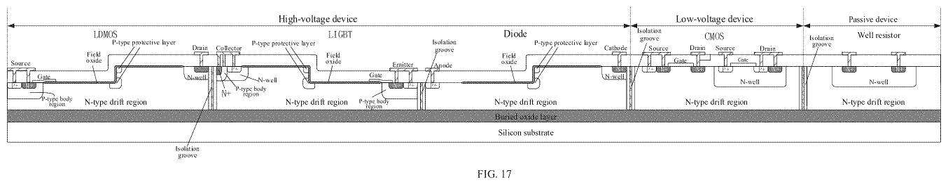

Taking the manufacturing of an SOI diode as an example, the structure after step S420 is shown in FIG. 15a. Referring to FIG. 14, the method for manufacturing an SOI diode further includes the following steps after step S420:
S721, an N-well is formed.

Referring to FIG. 15b, the N-well 334 can be formed by photolithography and ion implantation. The N-well 334 is formed on the second side of the drop structure.
S722, a field oxide layer is formed.

Referring to FIG. 15c, the field oxide layer 347 is formed on the surface of the drift region 330. The field oxide layer 347 can be formed by deposition or thermal oxidation.
S723, an anode region and a cathode region are formed.

Referring to FIG. 15d, the N+ cathode region (i.e., the second electrode leading-out region 344) is located in the N-well 334, and the P+ anode region (i.e., the first electrode leading-out region 342) is formed on the first side of the drop structure.
S724, an interlayer dielectric layer and a contact hole are formed.

The interlayer dielectric layer 350 is deposited, and then etched to form the contact hole. Thereafter, step S430 is performed to form the first electrode 362 and the second electrode 364, that is, the structure shown in FIG. 5 is obtained. The first electrode 362 is electrically connected to the P+ anode region, and the second electrode 364 is electrically connected to the N+ cathode region. The above steps S721 to S724 are suitable for the embodiment in which the step structure of the drift region is formed by reactive ion etching, and also suitable for the embodiment in which the step structure of the drift region is formed by secondary epitavy, except that the step structure formed by secondary epitavy is steeper.

It should be understood that, although the steps in the flowcharts of the present disclosure are shown in sequence as indicated by the arrows, these steps are not necessarily performed in the order indicated by the arrows. Unless otherwise clearly specified herein, these steps are performed without any strict sequence limitation, and may be performed in other orders. In addition, at least some steps in the flowcharts of the present disclosure may include a plurality of steps or a plurality of stages, and such steps or stages are not necessarily performed at a same moment, and may be performed at different moments. These steps or stages are not necessarily performed in sequence, and the steps or stages and at least some of other steps or sub-steps or sub-stages of other steps may be performed in turn or alternately.

In the description of the specification, reference terms such as “some embodiments”, “other embodiments”, and “ideal embodiments” mean that a particular feature, structure, material, or characteristic described in connection with the embodiment or example is included in at least one embodiment or example of the present disclosure. In the specification, illustrative descriptions of the above terms do not necessarily refer to a same embodiment or example.

The technical features in the above embodiments may be randomly combined. For concise description, not all possible combinations of the technical features in the above embodiments are described. However, all the combinations of the technical features are to be considered as falling within the scope of this specification provided that they do not conflict with each other.

The above embodiments only describe several implementations of the present disclosure, and their description is specific and detailed, but cannot therefore be understood as a limitation on the patent scope of the present disclosure. It should be noted that those of ordinary skill in the art may further make variants and improvements without departing from the conception of the present disclosure, and these all fall within the protection scope of the present disclosure. Therefore, the patent protection scope of the present disclosure should be subject to the appended claims.

1. A silicon-on-insulator semiconductor device, comprising:
a substrate;
a buried dielectric layer disposed on the substrate;
a first electrode;
a second electrode; and
a drift region disposed on the buried dielectric layer, wherein an upper surface of the drift region forms a drop structure comprising a first side adjacent to the first electrode, a second side adjacent to the second electrode, and a transition region between the first side and the second side, and an upper surface of the second side is higher than a bottom surface of the first side, such that a thickness of the drift region at the second side is greater than a thickness thereof at the first side;
wherein the first electrode and the second electrode are configured such that a voltage applied to the second electrode is greater than a voltage applied to the first electrode when a reverse bias voltage is applied to the device.

2. The silicon-on-insulator semiconductor device according to claim 1, wherein the device is a lateral double-diffused metal-oxide-semiconductor field effect transistor (LDMOS), the first electrode is a source, the second electrode is a drain, and the LDMOS further comprises a gate.

3. The silicon-on-insulator semiconductor device according to claim 1, wherein the device is a lateral insulated gate bipolar transistor (LIGBT), the first electrode is an emitter, the second electrode is a collector, and the LIGBT further comprises a gate.

4. The silicon-on-insulator semiconductor device according to claim 1, wherein the device is a diode, the first electrode is an anode, and the second electrode is a cathode.

5. The silicon-on-insulator semiconductor device according to claim 1, wherein the drop structure is a step structure comprising a first step surface located on the first side, a second step surface located on the second side, and a step wall located on the transition region, and a height difference between the second step surface and the first step surface is in a range from 3 μm to 10 μm.

6. The silicon-on-insulator semiconductor device according to claim 5, wherein an inclination angle of the step wall is in a range from 20 degrees to 90 degrees.

7. The silicon-on-insulator semiconductor device according to claim 5, wherein the drift region has a first conductivity type, the device further comprises a second conductivity type protective layer located in the drift region, the second conductivity type protective layer encloses a corner formed by the first step surface and the step wall and a corner formed by the second step surface and the step wall; wherein the first conductivity type is opposite to the second conductivity type.

8. The silicon-on-insulator semiconductor device according to claim 5, further comprising a first electrode leading-out region and a second electrode leading-out region that are disposed on the buried dielectric layer.

9. The silicon-on-insulator semiconductor device according to claim 8, further comprising a field oxide layer on the upper surface of the drift region extending from the second side adjacent to the second electrode to the first side adjacent to the first electrode.

10. The silicon-on-insulator semiconductor device according to claim 9, further comprising an interlayer dielectric layer, wherein the interlayer dielectric layer at least covers the field oxide layer, the first electrode leading-out region, and the second electrode leading-out region.

11. A silicon-on-insulator semiconductor process platform, comprising the silicon-on-insulator semiconductor device according to claim 1, and at least one of a complementary metal-oxide-semiconductor field effect transistor (CMOS) and a well resistor.

12. A method for manufacturing a silicon-on-insulator semiconductor device, comprising:
obtaining a wafer comprising a substrate, a buried dielectric layer on the substrate, and a drift region on the buried dielectric layer;
forming a drop structure on an upper surface of the drift region by photolithography and etching, wherein the drop structure comprises a first side, a second side, and a transition region between the first side and the second side, and an upper surface of the second side is higher than a bottom surface of the first side, such that a thickness of the drift region at the second side is greater than a thickness thereof at the first side; and
forming a first electrode and a second electrode, wherein the first side is a side adjacent to the first electrode, and the second side is a side adjacent to the second electrode;
wherein the first electrode and the second electrode are configured such that a voltage applied to the second electrode is greater than a voltage applied to the first electrode when a reverse bias voltage is applied to the device.

13. The method for manufacturing the silicon-on-insulator semiconductor device according to claim 12, wherein the drop structure is a step structure comprising a first step surface on the first side, a second step surface on the second side, and a step wall on the transition region,
prior to forming the first electrode and the second electrode, the method further comprises: forming a protective layer in the drift region at the step structure by ion implantation, wherein the protective layer encloses a corner formed by the first step surface and the step wall and a corner formed by the second step surface and the step wall.

14. The method for manufacturing the silicon-on-insulator semiconductor device according to claim 12, wherein the etching is a reactive ion etching process.

15. A method for manufacturing a silicon-on-insulator semiconductor device, comprising:
obtaining a wafer comprising a substrate, a buried dielectric layer on the substrate, and a first epitaxial layer on the buried dielectric layer;
forming a second epitaxial layer at a partial region of the first epitaxial layer, wherein a drop structure is formed at a boundary between the first epitaxial layer and the second epitaxial layer, the drop structure comprises a first side on a side of the second epitaxial layer, a second side on a side of the first epitaxial layer, and a transition region between the first side and the second side; and
forming a first electrode and a second electrode, wherein the first side is a side adjacent to the first electrode, and the second side is a side adjacent to the second electrode;
wherein the first electrode and the second electrode are configured such that a voltage applied to the second electrode is greater than a voltage applied to the first electrode when a reverse bias voltage is applied to the device.
